(19) United States
(12) Patent Application Publication
(10) Pub. No.: US 2006/0214704 A1
(43) Pub. Date: Sep. 28, 2006

(54) Load drive circuit

(75) Inventor: Masaji Nakano, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/352,334

(22) Filed: Feb. 13, 2006

(30) Foreign Application Priority Data
Mar. 24, 2005 (JP) 2005-087272
Mar. 24, 2005 (JP) 2005-087263

(51) Int. Cl. H03B 1/00

(52) U.S. Cl. 327/110

(57) ABSTRACT

The load drive circuit 1 includes a FET10, a clamp circuit 20, a control circuit 30, and a temperature measuring unit 40. The FET 10 is a transistor for driving a load 90. The clamp circuit 20 is connected between the gate and the drain of the FET 10. The clamp circuit 20 blocks a carrier flow passing from the gate to the drain when the gate-drain voltage of the FET 10 is not more than a predetermined clamp voltage. On the other hand, the clamp circuit 20 allows the carrier flow when the gate-drain voltage is more than the clamp voltage. The control circuit 30 controls a magnitude of the clamp voltage based upon an output from the temperature measuring unit 40, namely the temperature of the FET 10 measured by the temperature measuring unit 40.

This application is based on Japanese patent applications NO. 2005-087272 and 2005-087263, the contents of which are incorporated hereinto by reference.

### BACKGROUND

1. Technical Field

The present invention relates to a load drive circuit.

2. Related Art

An example of conventional load drive circuit is shown in Japanese Laid-open Patent Publication NO. 2002-84174. The load drive circuit described in the document has a FET (field-effect transistor) for driving a load and a clamp circuit connected between a gate and a drain of the FET. The clamp circuit controls the voltage between the gate and drain so that the voltage does not exceed a predetermined value of clamp voltage.

### SUMMARY OF THE INVENTION

It is preferable that the load drive circuit requires as short current-off time as possible, or the time for the current passing through the load to actually become zero after turned off the FET for driving the load. The current-off time may be reduced by higher clamp voltage setting. However, the higher the setting of clamp voltage became, the larger the power consumption of the FET for driving the load could be, and thereby leading to an increase in the peak temperature of the FET.

According to the present invention, there is provided a load drive circuit including a field-effect transistor which drives a load; a clamp circuit connected between a gate and a drain of the field-effect transistor, blocking carrier flow from the gate to the drain when a gate-drain voltage which is a voltage between the gate and the drain is not more than a predetermined clamp voltage, and allowing the carrier flow when the gate-drain voltage is more than the clamp voltage; and a control circuit controlling a magnitude of the clamp voltage.

As described above, a higher clamp voltage set with the aim of reducing the current-off time increases the peak temperature of the field-effect transistor. This means that the current-off time and the peak temperature trade off each other. The load drive circuit according to the present invention includes a control circuit controlling a magnitude of clamp voltage within a range of permissible upper limit value of the peak temperature in order to restrain the increase in the peak temperature and reduce the current-off time.

The load drive circuit may further include a temperature measuring unit measuring a temperature of the field-effect transistor, and the control circuit may control a magnitude of the clamp voltage based upon an output of the temperature measuring unit. In this case, the temperature of the field-effect transistor is not only controlled but also monitored to obtain higher control accuracy.

The control circuit may control the magnitude of the clamp voltage based upon a predetermined program. In this case, the clamp voltage can be controlled with a simple configuration.

According to the present invention, a load drive circuit can be obtained which can restrain an increase in the peak temperature of a transistor for driving a load and at the same time can reduce the current-off time.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing the first embodiment of the load drive circuit according to the present invention;

FIG. 2 is a circuit diagram showing an example of the configuration of the load drive circuit in FIG. 1;

FIG. 3 is a graph showing an example of controlling clamp voltage by way of control circuit;

FIG. 4 is a graph schematically showing a change of output voltage and output current in the conventional load drive circuit;

FIG. 5A is a graph schematically showing a temperature change of the FET for driving a load in the conventional load drive circuit;

FIG. 5B is a graph schematically showing a temperature change of the FET for driving a load in the load drive circuit according to the embodiment;

FIG. 6 is a graph showing simulation results of the load drive circuit according to a comparative example;

FIG. 7 is a graph showing simulation results of the load drive circuit according to the comparative example;

FIG. 8 is a graph showing simulation results of the load drive circuit according to the comparative example;

FIG. 9 is a graph showing a simulation result of the load drive circuit according to the embodiment;

FIG. 10 is a block diagram showing a load drive circuit according to a modified example of the embodiment;

FIG. 11 is a graph showing a modified example of controlling clamp voltage by way of control circuit;

FIG. 12 is a block diagram showing the second embodiment of the load drive circuit according to the present invention; and

FIG. 13 is a circuit diagram showing an example of configuration of the load drive circuit shown in FIG. 12.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

In the respective drawings, an identical code is given to a same element, and redundant explanations are omitted hereinafter.

### First Embodiment

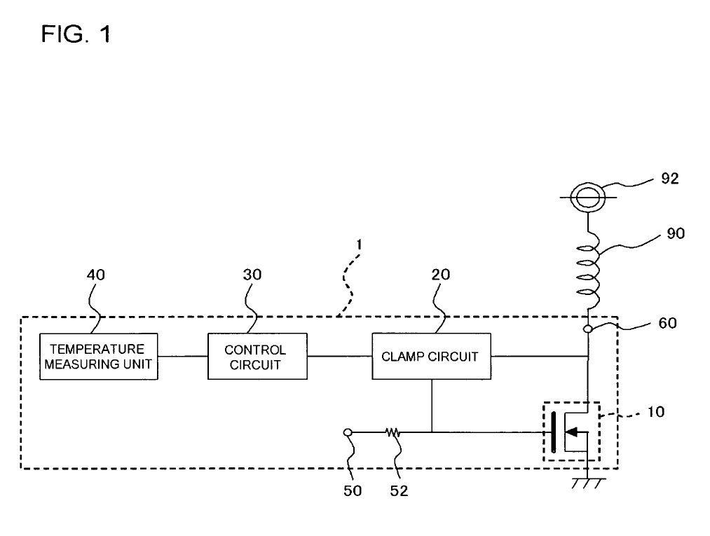

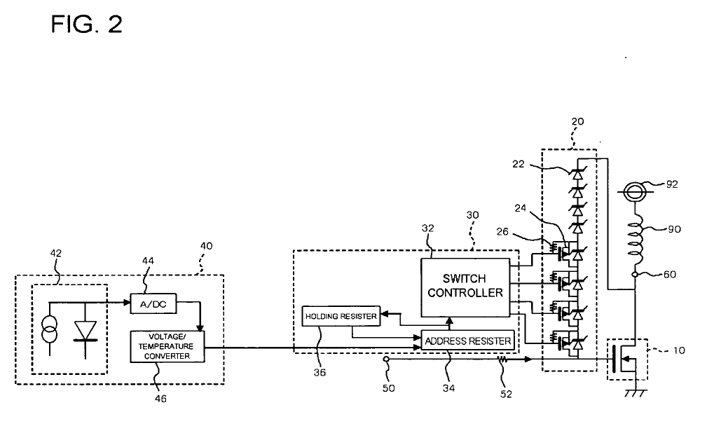

FIG. 1 is a block diagram showing the first embodiment of a load drive circuit according to the present invention. FIG. 2 is a circuit diagram showing an example of configuration of the load drive circuit according to FIG. 1. The load drive circuit 1 includes a FET 10, a clamp circuit 20, a control circuit 30, a temperature measuring unit 40, a gate control terminal 50, and a load connection terminal 60. The load connection terminal 60 has an end connected to the load 90. The other end of the load 90 is connected to the power supply terminal 92. The potential given to the power supply terminal 92 (power supply potential) is for example 12V.

The FET 10 according to the present embodiment is a transistor for driving load 90 and is of a N-conductive type. The source of the FET 10 is connected to the ground and the drain of the FET 10 to the load connection terminal 60, respectively. The gate of the FET 10 is connected to the gate control terminal 50 through a resistor 52. The gate control terminal 50 is a terminal for inputting control signal for controlling the gate of FET 10. The control signal switches to turn on/off the FET 10.

The clamp circuit 20 is connected between the gate and drain of the FET 10. That is, the clamp circuit 20 has one end connected to the gate and the other end connected to the drain of the FET 10. The clamp circuit 20 blocks the carrier flow (the carrier is an electron in this embodiment) passing from the gate to the drain when the gate-drain voltage of the FET 10 is not more than the predetermined clamp voltage. On the other hand, the clamp circuit 20 allows the carrier flow passing from the gate to the drain when the gate-drain voltage is more than the clamp voltage. In other words, the clamp circuit 20 blocks the current passing from the drain to the gate through the clamp circuit 20 when the gate-drain voltage is not more than the clamp voltage, while allows the current to pass from the drain to the gate through the clamp circuit 20 when the gate-drain voltage is more than the clamp voltage. The clamp circuit 20 is configured so that the clamp voltage is variable.

The clamp circuit 20, as shown in FIG. 2, includes a plurality (eight in the example) of Zener diodes 22 connected in series with each other. The Zener voltage of the Zener diode 22 is 7.5V for example. In FIG. 2, four of eight Zener diodes 22 have transfer gates 24 connected in parallel with each of the four Zener diodes 22. The transfer gate 24 is a P-type FET, and its source and drain are connected to the cathode and anode of the Zener diode 22, respectively. Between the source and the gate of the transfer gate 24 a resistor 26 is connected.

In the clamp circuit 20 with such configurations, the Zener diode 22 blocks the carrier flow passing from the gate to the drain of the FET 10 (from the anode to the cathode of the Zener diode 22) when the voltage applied to each Zener diode 22 is not more than the Zener voltage. The Zener diode 22 provided with the transfer gate 24, however, contributes to the blocking of the carrier when the transfer gate 24 is in the OFF-state, while it does not contribute to the blocking when the transfer gate 24 is in the ON-state. In the latter case, this is because that the carrier can flow from the anode to the cathode of the Zener diode 22 through the transfer gate 24.

Therefore, in the clamp circuit 20, the number of Zener diode 22 that contributes to blocking of the carrier flowing from the gate to the drain of the FET 10 is variable by switching on and off of the transfer gate 24. When, for example, all of four transfer gates 24 are in the OFF state, the number of Zener diodes 22 that contributes to the blocking of the carrier flow is eight. Similarly, when one of four transfer gates 24 is in the ON state and the three transfer gates 24 are in the OFF state, the number of Zener diode 22 that contributes to the blocking of the carrier flow is seven. In this case, the clamp voltage of the clamp circuit 20 is equal to a sum of Zener voltage that contributes to the blocking of the carrier flow.

The control circuit 30 controls a magnitude of clamp voltage of the clamp circuit 20. The control circuit 30 according to this embodiment controls the magnitude of the clamp voltage as will be described later based upon an output from the temperature measuring unit 40, that is, a temperature of the FET 10 measured at the temperature measuring unit 40. A junction temperature is used as the temperature of FET 10. Specifically, the control circuit 30 controls the magnitude of the clamp voltage so that the temperature of the FET 10 measured by the temperature measuring unit 40 closes to the predetermined target value. In other words, the control circuit 30 controls the magnitude of the clamp voltage in a way that the temperature is kept close to the target value during dynamic clamping. The target value is set lower than the allowable upper limit temperature of the FET 10. The allowable upper limit value used herein means a range of temperature within which correct operation of the FET 10 can be secured. The temperature is for example 150 degrees C.

As shown in FIG. 2, the control circuit 30 includes a switch controller 32, an address register 34, and a holding register 36. The switch controller 32 includes a memory circuit in which control rules used for controlling the clamp voltage is stored, and a driver controlling the gate of the transfer gate 24 of the clamp circuit 20. The memory circuit is for example a FLASH or a ROM. The driver is connected to the gate of each transfer gate 24. The control rules according to this embodiment are memorized as a form of LUT (Look Up Table). Specifically, in the switch controller 32, the output variable of the LUT is read from the addresses specified by the address register 34, and according to the output variable, the driver produces control signals to be sent to the transfer gate 24.

In this example, the control signals are combined in five ways as (i) (1,1,1,1), (ii) (0,1,1,1), (iii) (0,0,1,1), (iv) (0,0,0,1), and (v) (0,0,0,0). These combinations respectively mean as:

(i) Turn off all of four transfer gates 24;

(ii) Turn on one of four transfer gates 24 and turn off the other three transfer gates 24;

(iii) Turn on two of four transfer gates 24 and turn off the other two transfer gates 24;

(iv) Turn on three of four transfer gates 24 and turn off the other one transfer gates 24; and

(v) Turn on all of four transfer gates 24.

The combinations (i) to (v) correspond to a case in which the number of Zener diodes 22 that contribute to the blocking of the carrier flow is eight, seven, six, five and four respectively in the clamp circuit 20. In this way, the control circuit 30 changes the magnitude of the clamp voltage of the clamp circuit 20 by way of changing the number of Zener diode 22 that contributes to the blocking of the carrier flow among a plurality of Zener diodes 22 provided in the clamp circuit 20. The control circuit 30 switches on/off of the transfer gate 24 in order to determine whether the Zener diode 22 connected to the transfer gate 24 contributes to the blocking of the carrier flow or not.

There are three input variables of the LUT: a difference between a permissible upper limit value of the temperature of the FET 10 and an updated temperature (current temperature) measured by the temperature measuring unit 40; a difference between the permissible upper limit value and a temperature measured immediately before the above updated temperature (previous temperature); and a current magnitude of the clamp voltage. The control circuit 30 controls the magnitude of the clamp voltage based upon these input variables. Specifically, the afore-mentioned address register 34 specifies the address of the memory circuit provided in the switch controller 32 according to the combination of these input variables.

The address register 34 inputs the current temperature from the temperature measuring unit 40 and inputs the previous temperature from the holding register 36. In other words, the holding register 36 holds information on the updated temperature measured by the temperature measuring unit 40. The information is read by the address register 34 as the previous temperature when the next address is specified.

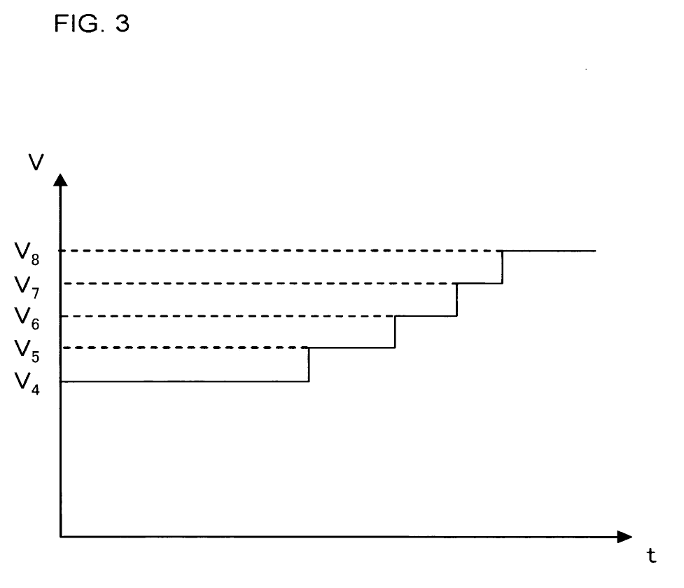

With reference to FIG. 3, an example of controlling the clamp voltage by control circuit 30 is described below. In a graph shown in FIG. 3, the axes of ordinate and abscissa represent a clamp voltage V and a time t respectively. In this example, the clamp voltage is set as V4. As time passes, the clamp voltage is controlled to be gradually increased with V5, V6, V7, and V8 in this sequence. The V4, V5, V6, V7, and V8 correspond to the cases in which the number of Zener diodes that contribute to the blocking of the carrier flow is four, five, six, seven and eight, respectively. This control pattern can be preferably adopted particularly in the case where the SOI substrate, which has worse heat releasing capability than the silicon substrate, is used as a semiconductor substrate in which the FET 10 is formed.

Referring now back to FIG. 1, the temperature measuring unit 40 is a temperature measuring means for measuring the temperature of the FET 10. As shown in FIG. 2, the temperature measuring unit 40 includes a temperature sensor 42, an AD converter 44 and a voltage/temperature converter 46. The temperature sensor 42 is for example a diode arranged near the FET 10. The AD converter 44 converts the output voltage of the temperature sensor 42 from analog to digital. The voltage/temperature converter 46 inputs the output voltage of the temperature sensor 42 converted to digital value by the AD converter 44, and then converts to the corresponding temperature information. The output of voltage/temperature converter 46 is input to the address register 34 as the current temperature.

The effects of load drive circuit 1 are described below. The load drive circuit 1 includes a control circuit 30 that controls a magnitude of clamp voltage of the clamp circuit 20. With this configuration, the load drive circuit 1 may restrain an increase in the peak temperature by controlling the magnitude of the clamp voltage within a range under a permissible upper limit value of the peak temperature of the FET10, thereby reducing the current-off time.

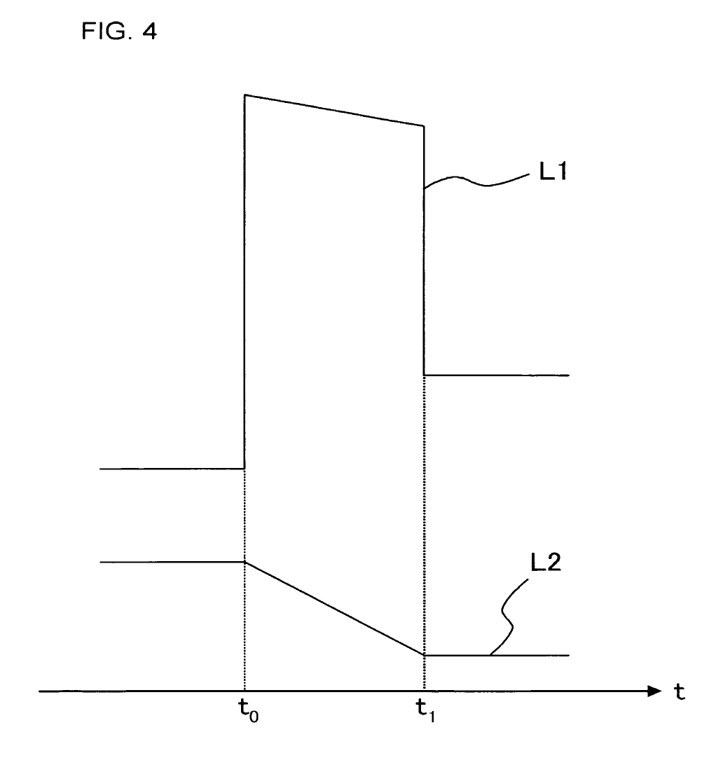

In contrast, because the load drive circuit described in Japanese Laid-open Patent Publication NO. 2002-84174 is not configured to control a magnitude of clamp voltage, the clamp voltage is always kept constant when the output is turned off during dynamic clamping. The output voltage and the output current of the load drive circuit changes as shown in FIG. 4. The output voltage used herein means a voltage at a drain side (the side connected to the load) of the FET for driving the load, and the output current means a current flowing therethrough. In FIG. 4, lines L1 and L2 show a change of the output voltage and output current, respectively. The time t0 and t1 show a time when the FET is turned off and a time when output current is turned zero, respectively. The current-off time is then derived from an expression (t1−t0).

As shown in FIG. 4, just after the FET is turned off, the load still keeps the current flowing through, thereby causing a rapid increase in the output voltage. When the output voltage exceeds the clamp voltage, the current flows from the drain to the gate of the FET though the clamp circuit, and thereby turning on the FET. This consumes at the FET the energy stored in the load. At time t1, the output current is turned zero and the output voltage becomes equal to the source voltage.

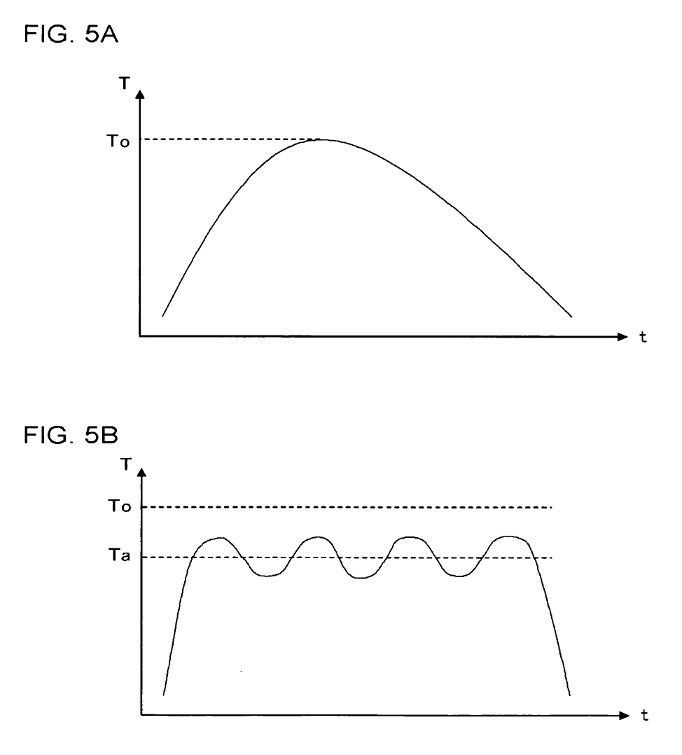

The change of temperature during dynamic clamping of the FET is generally shown in FIG. 5A. That is, the temperature of the FET gradually increases after the beginning of the clamping, and then gradually decreases after reaching to the peak temperature T0.

On the other hand, in the case where the clamp voltage is controlled by the control circuit 30 in the load drive circuit 1 as shown in FIG. 3, the temperature change of the FET 10 during the dynamic clamping is as shown in FIG. 5b. In other words, the temperature of the FET 10 changes near the target value Ta. This is because the clamp voltage is controlled to be relatively large when the temperature of the FET is relatively low, whereas the clamp voltage is controlled to be relatively small when the temperature of the FET is relatively high, at the conventional temperature profile (refer to FIG. 5A) in the load drive circuit 1. The energy consumption in the FET 10 is thus kept large and the energy stored in the load 90 is consumed in a short time, and thereby achieving reduction of current-off time.

The load drive circuit 1 includes the temperature measuring unit 40 measuring the temperature of the FET 10. The control circuit 30 controls the magnitude of the clamp voltage based upon the output of the temperature measuring unit 40. Because the temperature of the FET 10 is not only controlled but also monitored, high control accuracy can be achieved. It is not essential, however, that the load drive circuit 1 includes the temperature measuring unit 40. The control circuit 30 may, for example, be controlled according to a predetermined program.

The control circuit 30 controls the magnitude of the clamp voltage so that the temperature of the FET 10 become closer to a predetermined target value. When the temperature of the FET 10 is relatively low, the clamp voltage is set high to make the energy consumption in the FET 10 larger. On the other hand, when the temperature of the FET 10 is relatively high, the clamp voltage is set low to make the energy consumption in the FET 10 smaller. Accordingly, the current-off time is reduced more effectively.

The clamp circuit 20 includes a plurality of the Zener diodes 22 connected in series with each other, and thereby achieving a simpler configuration of the clamp circuit 20.

The control circuit 30 changes the magnitude of the clamp voltage by changing the number of Zener diode 22 that contributes to blocking the carrier flow among the Zener diodes 22, thereby changing the magnitude of the clamp voltage with a simple mechanism.

The control circuit 30 switches whether the Zener diode 22 connected to the transfer gate 24 contributes to the blocking of the carrier flow by turning on or off the transfer gate 24. Accordingly, the number of stages of the clamp circuit can be changed easily.

The control circuit 30 controls the magnitude of the clamp voltage based upon a difference between a permissible upper limit value of the temperature of the FET 10 and an updated temperature measured by the temperature measuring unit 40, a difference between the above-mentioned permissible upper limit value and a temperature measured by the temperature measuring unit 40 immediately before the updated temperature is measured, and a current magnitude of the clamp voltage. Accordingly, such control that the temperature of the FET 10 is kept as constant as possible can be achieved with high accuracy.

In the control circuit 30, the magnitude of the clamp voltage to be controlled is determined referring to the LUT. Accordingly, high speed control is achieved.

The use of FLASH as a memory circuit of the control circuit 30 allows rewriting of the control rule.

### Second Embodiment

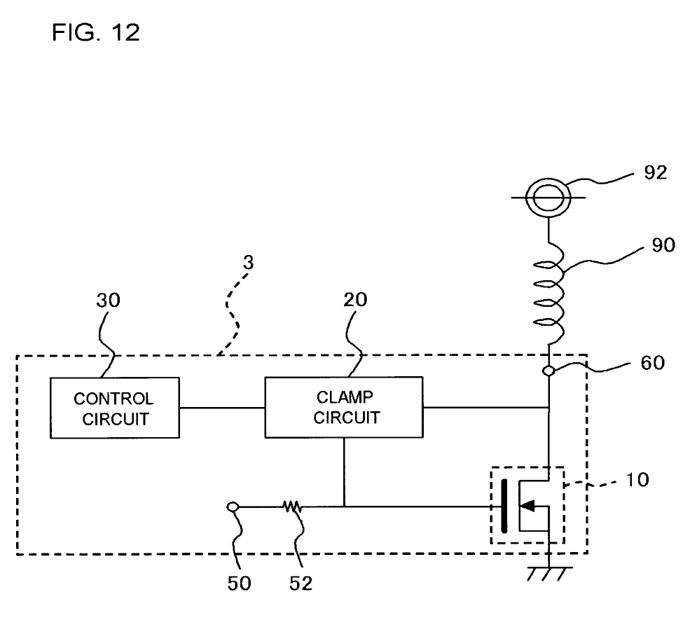

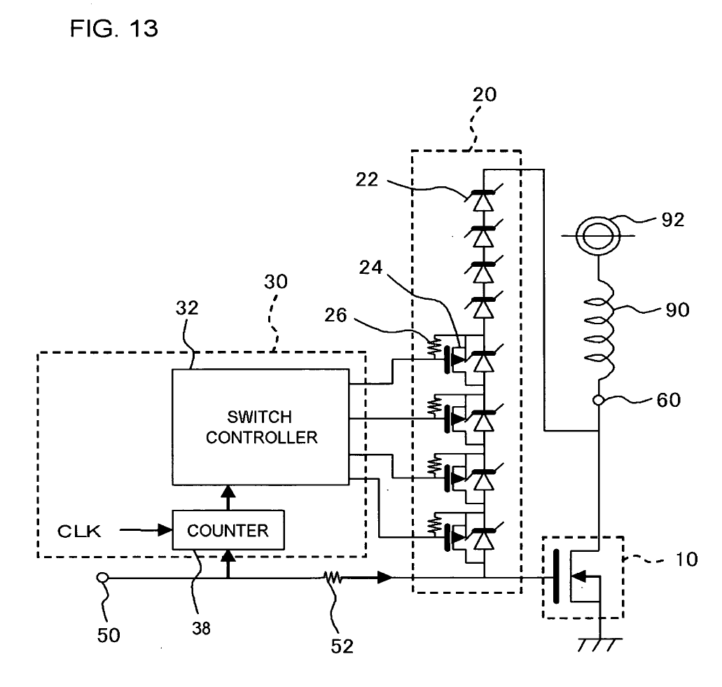

FIG. 12 is a block diagram showing the second embodiment of the load drive circuit according to the present invention. FIG. 13 is a circuit flow diagram showing an example of the configuration of the load drive circuit in FIG. 12. The load drive circuit 3 includes a FET 10, a clamp circuit 20, a control circuit 30, a gate control terminal 50, and a load connection terminal 60. One end of the load 90 is connected to the load connection terminal 60. The load 90 has the other end connected to the power supply terminal 92. The potential given to the power supply terminal 92 (power supply potential) is, for example, 12V. The configurations of the FET 10, the clamp circuit 20, the gate control terminal 50 and the load connection terminal 60 are equal to those in the load drive circuit 1.

In this embodiment, the control circuit 30 controls a magnitude of clamp voltage based upon predetermined program. Specifically, the control circuit 30 controls the magnitude of the clamp voltage so that the temperature of the FET 10 become close to the predetermined target value based upon the above-mentioned program. This means that the control circuit 30 controls the clamp voltage so that the above temperature is kept close to the target value during dynamic clamping. The target value is set lower than the permissible upper limit value of the temperature of FET 10. The allowable upper limit value used herein means a range of temperature within which correct operation of the FET 10 can be secured. The temperature is for example 150 degrees C. The above program may be configured in such a way that the values of inductance and resistance of the load 90 are given as parameters.

As shown in FIG. 13, the control circuit 30 includes a switch controller 32 and a counter 38. The switch controller 32 have a memory circuit storing the above program used for controlling the clamp voltage, and a driver controlling the gate of the transfer gate 24 in the clamp circuit 20. The memory circuit is FLASH or ROM, for example. The driver is connected to the gate of each transfer gate 24. The signal from the counter 38 is input to the switch controller 32. In the switch controller 32, when the count reaches to a certain value, the control signals to be sent from the driver to the gate of each transfer gate 24 are changed.

In this example, the control signals are combined in five ways as (i) (1,1,1,1), (ii) (0,1,1,1), (iii) (0,0,1,1), (iv) (0,0,0,1), and (v) (0,0,0,0). Each combination means as mentioned above.

The combinations (i) to (v) correspond to a case in which the number of Zener diodes 22 that contribute to the blocking of the carrier flow is eight, seven, six, five and four respectively in the clamp circuit 20. In this way, the control circuit 30 changes the magnitude of the clamp voltage of the clamp circuit 20 by way of changing the number of Zener diode 22 that contributes to the blocking of the carrier flow among a plurality of Zener diodes 22 provided in the clamp circuit 20. The control circuit 30 switches on/off of the transfer gate 24 in order to determine whether the Zener diode 22 connected to the transfer gate 24 contributes to the blocking of the carrier flow or not.

As shown above, in the above program, control patterns such as what the initial value of the clamp voltage is, what the changed value of the clamp voltage is, and what the count at which the clamp voltage should be changed is.

An example of controlling clamp voltage by control circuit 30 is as shown in FIG. 3.

The effects of load drive circuit 3 are described below. The load drive circuit 3 includes the control circuit 30 that controls the magnitude of clamp voltage of the clamp circuit 20. The load drive circuit 3 can thus restrain an increase in the peak temperature by controlling the magnitude of the clamp voltage within a range that does not exceed the permissible upper limit value of the peak temperature of the FET10 and reduce the current-off time.

Also in this embodiment, when the clamp voltage is controlled by the control circuit 30 as shown in FIG. 3, the temperature of the FET 10 during dynamic clamping changes as generally shown in FIG. 5B.

The control circuit 30 controls the magnitude of the clamp voltage according to the predetermined program. Accordingly, the clamp voltage can be controlled with a simple configuration. In the load drive circuit 3, however, the clamp voltage is not necessarily controlled according to the program. For example, a temperature measuring unit measuring a temperature of the FET 10 may be provided, and control circuit 30 may be configured to control the magnitude of the clamp voltage based upon the output from the temperature measuring unit.

The control circuit 30 controls the magnitude of the clamp voltage according to the afore-mentioned program so that the temperature of the FET 10 become close to the predetermined target value. When the temperature of the FET 10 is relatively low, the clamp voltage is set high to make the energy consumption in the FET 10 larger. On the other hand, when the temperature of the FET 10 is relatively high, the clamp voltage is set low to make the energy consumption in the FET 10 smaller. Accordingly, the current-off time can be reduced more effectively.

The clamp circuit 20 includes a plurality of Zener diodes 22 connected in series with each other, and thereby achieving a simple configuration of the clamp circuit 20.

The control circuit 30 changes the magnitude of the clamp voltage by changing the number of Zener diode 22 contributing to blocking the carrier flow among the Zener diodes 22. Accodingly, the magnitude of the clamp voltage can be changed with a simple mechanism.

The control circuit 30 switches on/off of the transfer gate 24 in order to determine whether the Zener diode 22 connected to the transfer gate 24 contributes to the blocking of the carrier flow or not. Accordingly, the number of stages of the clamp circuit can be changed easily.

The use of FLASH as a memory circuit of the control circuit 30 allows rewriting of the program.

When the program is configured in such a way that the values of the inductance and resistance of the load 90 are given as the parameters, the control circuit 30 can control the clamp voltage in accordance with a property of the load 90 connected to the load connection terminal 60. Accordingly, the load drive circuit 3 which can be used for wide applications is achieved.

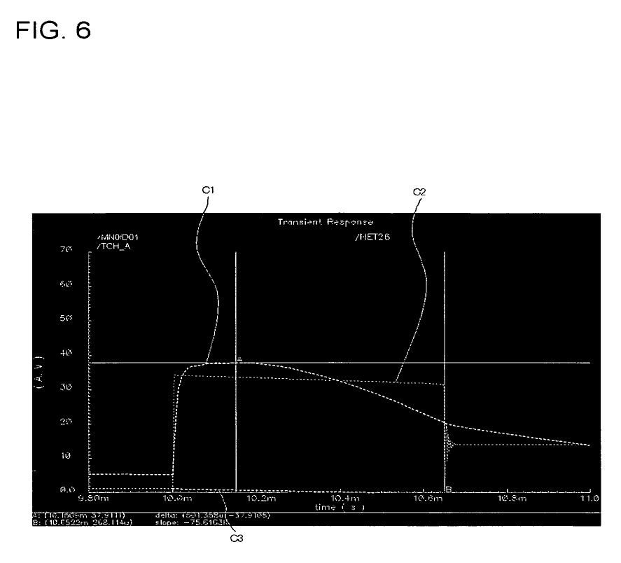

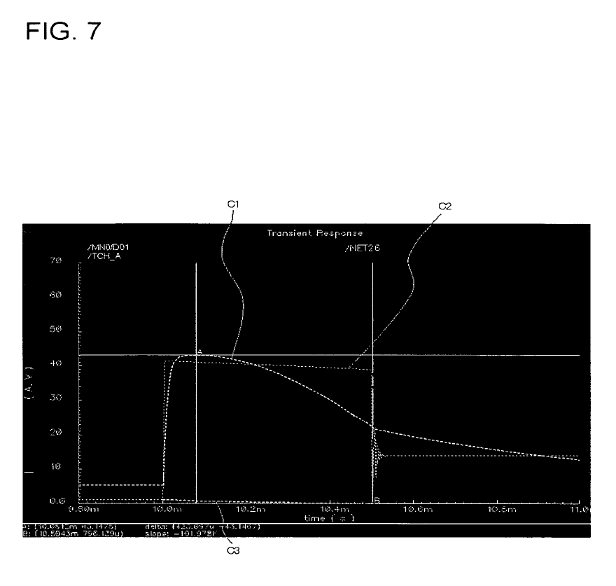

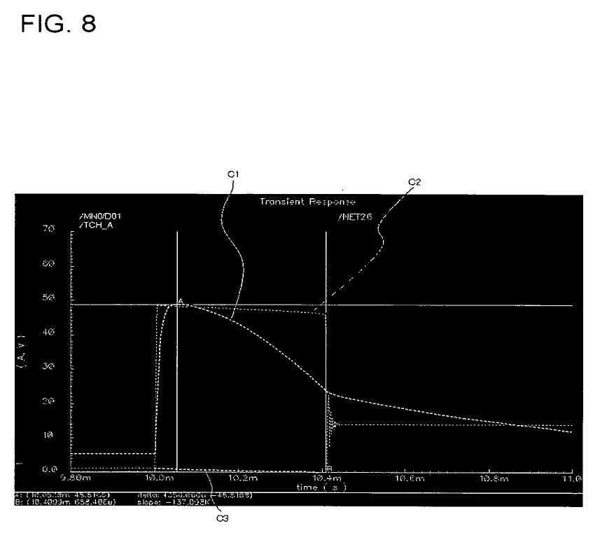

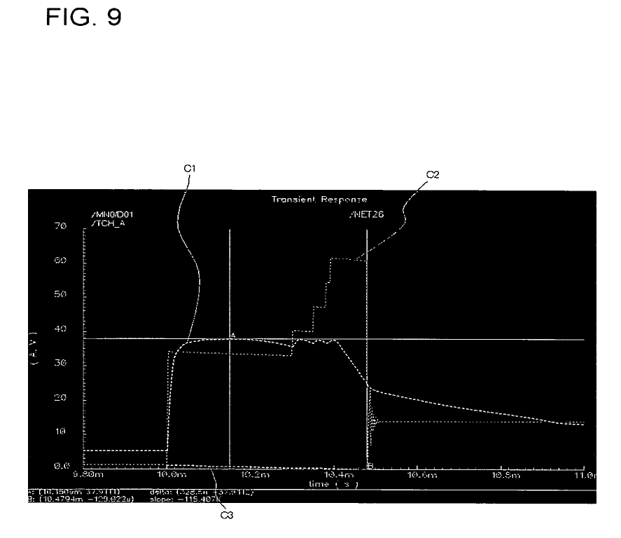

With reference to FIGS. 6 to 9, simulation results confirming effects of each embodiment shown above are described herein below. FIGS. 6, 7 and 8 show results in which the clamp voltage was not controlled but kept constant during dynamic clamping, and four, five and six stages of Zener diodes are provided, respectively. On the other hand, FIG. 9 shows a result in which the clamp voltage was controlled according to the program. In each drawing, graphs C1, C2, and C3 illustrate a temperature of the FET for driving a load, an output voltage and an output current, respectively. The axis of ordinate indicates temperature (degrees C.), voltage (V) and current (A), while that of abscissa indicates time(s).

In this simulation, the inductance and resistance of the load 90 are 15 mH and 12 ohms, respectively. The power supply voltage of the power supply terminal 92 is 14V. The Zener voltage of each Zener diode is approximately 7.5V. The clamp voltages in FIGS. 6, 7, and 8 are approximately 30V, 37.5V, and 45V, respectively.

Table. 1 shows a summary of the above simulation results. In the table, “A” indicates a case shown in FIG. 9 in which the clamp voltage is controlled, while “B”, “C”, and “D” respectively corresponds to FIGS. 6, 7, and 8. In FIG. 6, for example, a transistor for driving the load is turned off at 10.0 ms, and the output voltage settles back to the power supply voltage at 10.65 ms, at which the current-off time is shown as 650 ms. Referring now to the temperature, the FET has a temperature of 5 degrees C. immediately before turned off, and then the temperature reaches to a peak of 38 degrees C. during dynamic clamping. This indicates that the temperature increases by 33 degrees C. The comparison of this with FIGS. 6 to 8 shows that larger clamp voltage can reduce the current-off time, but increases the peak temperature (a degree of temperature increase).

In contrast, the clamp voltage is switched during dynamic clamping in FIG. 9. In this simulation, the program is set to change the number of Zener diodes contributing to the blocking of the carrier from the four to eight stages. As shown in FIG. 9, the output voltage is changed step by step in accordance with the change of the clamp voltage in which the current-off time is 480 us (microsecond), and the temperature increase is 33 degrees C. These results indicate that by controlling the clamp voltage the increase in the peak temperature can be restrained and at the same time the current-off time can be reduced. In the load drive circuit 1, the aim of controlling the clamp voltage with measuring the temperature of the FET 10 is to reduce the current-off time by such feedback control that a relatively flat temperature profile as shown in FIG. 9 is achieved.

TABLE 1

| | INCREASING DEGREE | |
|---|---|---|
| | OF TEMPERATURE | CURRENT-OFF TIME |
| A | 33° C. | 480 μs |
| B | 33° C. | 650 μs |
| C | 38° C. | 504 μs |
| D | 44° C. | 410 μs |

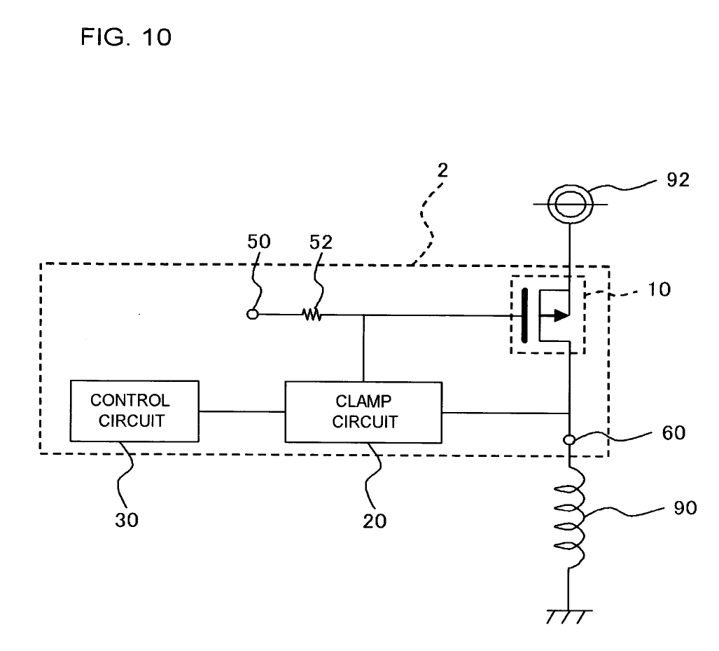

The load drive circuit according to the present invention is not limited to the above embodiments, however, various modifications can be made. In the above embodiments for example the FET 10 is connected to the low side of the load, however, the FET 10 may also be connected to the high side of the load 90 as shown in FIG. 10. In the load drive circuit 2, the FET 10 is of P-type conduction. The source and the drain of the FET 10, respectively is connected to the power supply terminal 92 and the load connection terminal 60, respectively.

Similarly as with the case of the load drive circuits 1, 3, the clamp circuit 20 is connected between the gate and the drain of the FET 10. The clamp circuit 20 blocks the flow of carrier (positive hole in this example) traveling from the gate to the drain when the gate-drain voltage of the FET 10 is smaller than or equal to the predetermined clamp voltage. On the other hand, the clamp circuit 20 allows the flow of carrier traveling from the gate to the drain when the gate-drain voltage exceeds the clamp voltage. In the load drive circuit 2, the Zener diode 22 included in the clamp circuit 20 has a cathode connected to the gate and an anode connected to the drain of the FET 10.

The afore-mentioned load drive circuit may be provided at both sides of the load 90. Specifically, the load drive circuit 1 or the load drive circuit 3 may be provided at the low side, and the load drive circuit 2 at the high side.

The number of Zener diodes 22 provided in the clamp circuit 20 is not limited to eight but may be of any plural number. Moreover, in the examples of the above embodiments, only a part of the Zener diodes 22 are provided with the transfer gate 24, however, all of the Zener diodes 22 may be provided with the transfer gate 24.

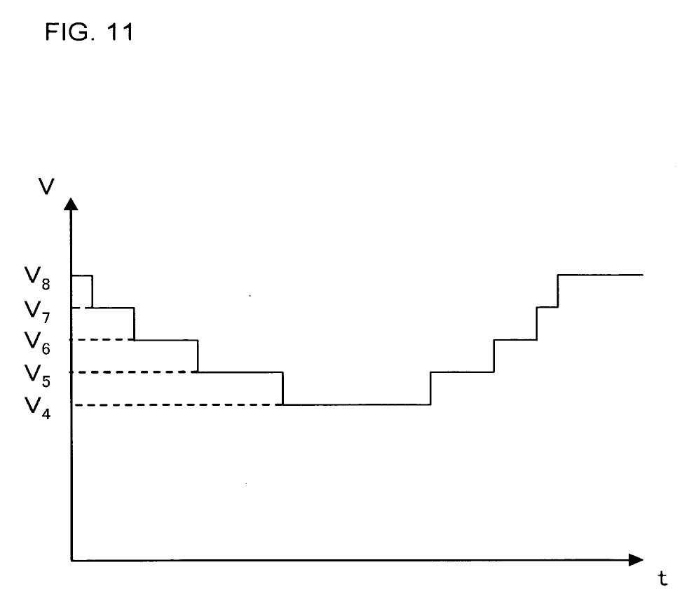

Controlling of the clamp voltage by way of the control circuit 30 are not limited to the one described in FIG. 3, however, various patterns may be made. FIG. 11 shows a graph for illustrating an example of modification in which the control circuit 30 controls the clamp voltage. In this example, the clamp voltage is set to V8, and controlled to keep falling gradually with V7, V6, V5, and V4 in this sequence as time passes. The clamp voltage stops falling at a point of V4 and then gradually goes upward with V5, V6, V7, and V8 in this sequence. This control pattern can be preferably adopted particularly in the case where the silicon substrate, which has better heat releasing capability than the SOI substrate, is used as a semiconductor substrate in which the FET 10 is formed.

It is apparent that the present invention is not limited to the above embodiment, and may be modified and changed without departing from the scope and spirit of the invention.

What is claimed is:

1. A load drive circuit, comprising:
a field-effect transistor which drives a load;
a clamp circuit connected between a gate and a drain of said field-effect transistor, blocking carrier flow from said gate to said drain when a gate-drain voltage which is a voltage between said gate and said drain is not more than a predetermined clamp voltage, and allowing said carrier flow when said gate-drain voltage is more than said clamp voltage; and
a control circuit controlling a magnitude of said clamp voltage.

2. The load drive circuit as set forth in claim 1, further comprising a temperature measuring unit measuring a temperature of said field-effect transistor;
wherein said control circuit controls a magnitude of said clamp voltage based upon an output of said temperature measuring unit.

3. The load drive circuit as set forth in claim 2, wherein said control circuit controls said magnitude of said clamp voltage so that said temperature become close to a predetermined target value.

4. The load drive circuit as set forth in claim 1, wherein said clamp circuit is configured to comprise a plurality of Zener diodes connected in series with each other.

5. The load drive circuit as set forth in claim 4, wherein said control circuit changes said magnitude of said clamp voltage by changing the number of Zener diodes contributing to blocking said carrier flow of said plurality of Zener diodes.

6. The load drive circuit as set forth in claim 5, further comprising a transfer gate connected in parallel with each one of a part or all of said plurality of Zener diodes;
wherein said control circuit switches whether said Zener diode connected to said transfer gate contributes to blocking said carrier flow by switching on/off said transfer gate.

7. The load drive circuit as set forth in claim 2, wherein said control circuit controls said magnitude of said clamp voltage based upon a difference between a permissible upper limit value of the temperature of said field-effect transistor and an updated temperature measured by said temperature measuring unit, a difference between said permissible upper limit value and a temperature measured by said temperature measuring unit immediately before said updated temperature is measured, and a current magnitude of said clamp voltage.

8. The load drive circuit as set forth in claim 1, wherein said control circuit controls said magnitude of said clamp voltage based upon a predetermined program.

9. The load drive circuit as set forth in claim 8, wherein said control circuit controls said magnitude of said clamp voltage so that a temperature of said field-effect transistor become close to a predetermined target value according to said program.
